(19) United States
(12) Patent Application Publication
(10) Pub. No.: US 2022/0336149 A1
(43) Pub. Date: Oct. 20, 2022

(54) IGNITION COIL DEVICE FOR INTERNAL COMBUSTION ENGINE

(71) Applicant: Mitsubishi Electric Corporation, Tokyo (JP)

(72) Inventors: Daisuke SUZUKI, Tokyo (JP); Shuji YAMADA, Tokyo (JP)

(73) Assignee: Mitsubishi Electric Corporation, Tokyo (JP)

(21) Appl. No.: 17/572,065

(22) Filed: Jan. 10, 2022

(30) Foreign Application Priority Data
Apr. 14, 2021 (JP) 2021-068091

(51) Int. Cl. H01F 38/12; H05K 7/20; H01F 27/02; H05K 1/02

(52) U.S. Cl. CPC H01F 38/12; H05K 7/2039; H01F 27/02; H05K 1/0203

(57) ABSTRACT

Provided is an ignition coil device for an internal combustion engine with which a reduction in performance can be suppressed. In an ignition coil device for an internal combustion engine, a case main body houses an ignition coil device main body and an igniter. The igniter includes a circuit board and lead frames provided on the circuit board. The circuit board includes a substrate having a first surface and a second surface formed thereon. The substrate is arranged in a state in which the first surface faces a connector, and the second surface faces the ignition coil device main body. The connector includes connector conductors. The lead frames are provided on the first surface in a state of being opposed to the connector conductors.

### BACKGROUND OF THE INVENTION

### Field of the Invention

This disclosure relates to an ignition coil device for an internal combustion engine.

### Description of the Related Art

In the related art, there is known an ignition coil device for an internal combustion engine in which the inside of an insulating case housing a primary coil, a secondary coil, and an igniter is filled with an insulating resin (see, for example, Patent Literature 1).

### CITATION LIST

### Patent Literature

[PTL 1] JP 2002-48046 A

### SUMMARY OF THE INVENTION

In the related-art ignition coil device for an internal combustion engine as described in the Patent Literature 1, the insulating resin makes it difficult to radiate heat generated in the igniter to the outside. As a result, the temperature of the igniter is increased, and there is a fear that performance of the igniter may be reduced. Therefore, there is a fear that performance of the ignition coil device for an internal combustion engine may be reduced.

This disclosure has been made to solve the above-mentioned problem, and therefore has an object to provide an ignition coil device for an internal combustion engine with which a reduction in performance can be suppressed.

According to one embodiment of this disclosure, there is provided an ignition coil device for an internal combustion engine, including: an ignition coil device main body; an igniter configured to control power supply to the ignition coil device main body; an insulating case including a case main body housing the ignition coil device main body and the igniter; and a connector provided to the case main body, the case main body having internal space filled with a filler covering the ignition coil device main body and the igniter, the igniter being arranged between the connector and the ignition coil device main body, the igniter including a circuit board and a heat radiating member provided on the circuit board, the connector including a connector conductor electrically connected to the circuit board, the circuit board including a substrate having a first surface and a second surface formed thereon, the substrate being arranged in a state in which the first surface faces the connector and the second surface faces the ignition coil device main body, the heat radiating member having a thermal conductivity that is higher than a thermal conductivity of the substrate, the heat radiating member being provided on the first surface in a state of being opposed to the connector conductor.

According to the ignition coil device for an internal combustion engine of this disclosure, the reduction in performance of the ignition coil device for an internal combustion engine can be suppressed.

### BRIEF DESCRIPTION OF THE DRAWINGS

FIG. 1 is a top view for illustrating an ignition coil device for an internal combustion engine according to a first embodiment of this disclosure.

FIG. 2 is a sectional view taken along the line II-II of FIG. 1.

FIG. 3 is an enlarged view for illustrating a connector module of FIG. 2.

FIG. 4 is a perspective view for illustrating the connector module of FIG. 3.

FIG. 5 is a sectional view for illustrating a main part of an ignition coil device according to a second embodiment of this disclosure.

FIG. 6 is a sectional view for illustrating an ignition coil device according to a third embodiment of this disclosure.

FIG. 7 is a sectional view for illustrating a main part of an ignition coil device according to a fourth embodiment of this disclosure.

### DESCRIPTION OF THE EMBODIMENTS

### First Embodiment

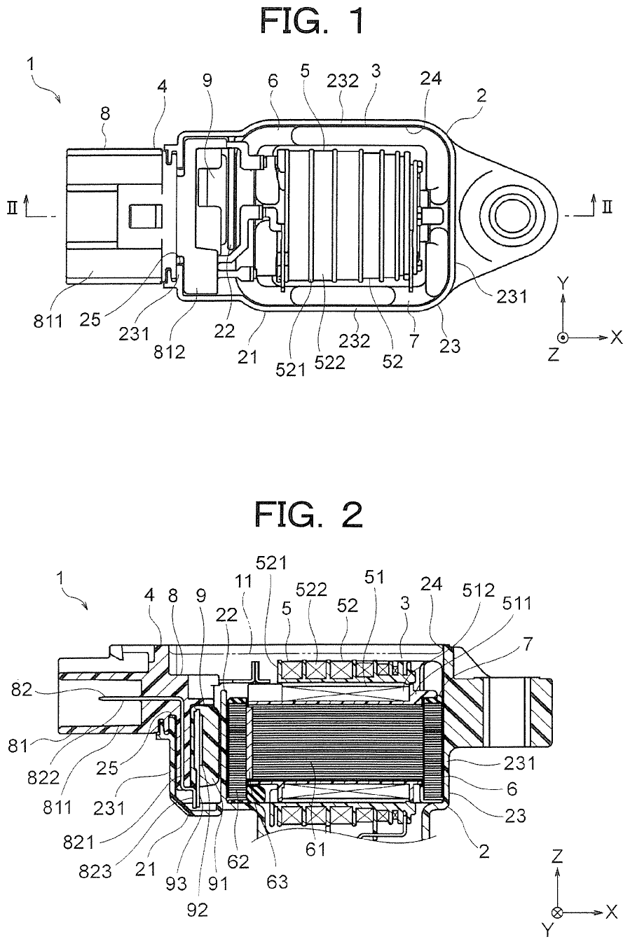

FIG. 1 is a top view for illustrating an ignition coil device for an internal combustion engine according to a first embodiment of this disclosure. Further, FIG. 2 is a sectional view taken along the line II-II of FIG. 1. In the figures, an ignition coil device 1 serving as the ignition coil device for an internal combustion engine is a device configured to supply a voltage to an ignition plug housed in a plug hole of the internal combustion engine. The ignition coil device 1 is arranged to be opposed to the plug hole. The ignition coil device 1 includes an insulating case 2, an ignition coil device main body 3, and a connector module 4.

The insulating case 2 is made of an insulating material. As the material forming the insulating case 2, a resin is used. The insulating case 2 includes a case main body 21 and a rib 22.

At one end of the case main body 21 in a thickness direction Z of the ignition coil device 1, an opening 24 is formed. Internal space of the case main body 21 is open to the outside of the case main body 21 through the opening 24. The case main body 21 is arranged with the opening 24 facing the side of the internal combustion engine opposite to the plug hole side. The case main body 21 also has a peripheral wall portion 23. The peripheral wall portion 23 surrounds the internal space and the opening 24 of the case main body 21.

In this specification, a direction orthogonal to the thickness direction Z of the ignition coil device 1 is defined as a depth direction X of the ignition coil device 1. Further, a direction orthogonal to both of the thickness direction Z of the ignition coil device 1 and the depth direction X of the ignition coil device 1 is defined as a width direction Y of the ignition coil device 1.

The peripheral wall portion 23 includes a pair of first opposed walls 231 opposed to each other in the depth direction X of the ignition coil device 1, and a pair of second opposed walls 232 opposed to each other in the width direction Y of the ignition coil device 1.

Of the pair of first opposed walls 231, one first opposed wall 231 has a cutout portion 25 formed therein. The cutout portion 25 is open at an end on the opening 24 side of the one first opposed wall 231. The internal space of the case main body 21 is open to the outside of the case main body 21 through the cutout portion 25.

The rib 22 is formed on the case main body 21. Further, the rib 22 is arranged in the internal space of the case main body 21. The internal space of the case main body 21 is divided into a first space and a second space by the rib 22. The rib 22 is a plate-like portion orthogonal to the depth direction X of the ignition coil device 1. The first space and the second space are adjacent to each other in the depth direction X of the ignition coil device 1. The rib 22 is arranged between the first space and the second space. A capacity of the first space is larger than a capacity of the second space. The second space is open to the outside of the case main body 21 through the cutout portion 25.

The ignition coil device main body 3 is housed in the first space of the case main body 21. The ignition coil device main body 3 includes a coil assembly 5, a core structure 6, and a core cover 7.

The coil assembly 5 includes a primary coil body 51 and a secondary coil body 52. Each of the primary coil body 51 and the secondary coil body 52 has a tubular shape. The primary coil body 51 is arranged inside the secondary coil body 52. Further, the primary coil body 51 is arranged coaxially with the secondary coil body 52. In other words, the primary coil body 51 and the secondary coil body 52 have a common axis. The coil assembly 5 is arranged under a state in which a direction along the common axis of the primary coil body 51 and the secondary coil body 52 is the same with the depth direction X of the ignition coil device 1.

The primary coil body 51 includes a primary bobbin 511 and a primary coil 512. The primary bobbin 511 has a tubular shape. The primary coil 512 is provided on the outer periphery of the primary bobbin 511. The primary coil 512 is formed of a wire wound around the primary bobbin 511.

The secondary coil body 52 includes a secondary bobbin 521 and a secondary coil 522. The secondary bobbin 521 has a tubular shape. The secondary coil 522 is provided on the outer periphery of the secondary bobbin 521. The secondary coil 522 is formed of a wire wound around the secondary bobbin 521. The secondary coil 522 is electrically connected to the ignition plug.

Each of the primary bobbin 511 and the secondary bobbin 521 is made of an insulating material. As the material forming each of the primary bobbin 511 and the secondary bobbin 521, a resin is used.

The core structure 6 includes a center core 61, a side core 62, and a magnet 63.

The center core 61 is provided in the coil assembly 5. Further, the center core 61 is arranged inside the coil assembly 5. In other words, the center core 61 is arranged inside each of the primary coil body 51 and the secondary coil body 52. The center core 61 is an I-shaped magnetic member having an axis along the depth direction X of the ignition coil device 1. The center core 61 is formed of a plurality of electromagnetic steel sheets laminated in the thickness direction Z of the ignition coil device 1.

The side core 62 is an O-shaped magnetic member arranged along the peripheral wall portion 23 of the case main body 21. The side core 62 is formed into an O shape by combining two U-shaped partial cores. The side core 62 is formed of a plurality of electromagnetic steel sheets laminated in the thickness direction Z of the ignition coil device 1. The center core 61 and the coil assembly 5 are arranged inside the side core 62. One end of the center core 61 in the depth direction X of the ignition coil device 1 is connected to an inner peripheral surface of the side core 62 via the magnet 63. The other end of the center core 61 in the depth direction X of the ignition coil device 1 is directly connected to the inner peripheral surface of the side core 62. As a result, the center core 61 is provided to the side core 62.

The magnet 63 is a plate-like permanent magnet interposed between the inner peripheral surface of the side core 62 and the center core 61. In the first embodiment, the magnet 63 is interposed between the end closer to the rib 22 of the both ends of the center core 61 in the depth direction X of the ignition coil device 1 and the inner peripheral surface of the side core 62. In the core structure 6, the center core 61, the side core 62, and the magnet 63 form a closed magnetic circuit.

Magnetic fluxes generated by power supply to the primary coil 512 pass through the closed magnetic circuit of the core structure 6. The magnet 63 is magnetized in a direction opposite to a direction of the magnetic fluxes generated by the power supply to the primary coil 512.

The core cover 7 covers a part of the side core 62. The core cover 7 is made of an insulating material. As the material forming the core cover 7, thermoplastic elastomer is used. In the first embodiment, a portion of the inner peripheral surface of the side core 62 other than the portion to which the center core 61 is connected is covered by the core cover 7. Further, in the first embodiment, both ends of the side core 62 in the thickness direction Z of the ignition coil device 1 are also covered by the core cover 7. In the first embodiment, an outer peripheral surface of the side core 62 is not covered by the core cover 7. The core cover 7 has a thermal conductivity of 0.5 W/m·K or less.

The connector module 4 includes a connector 8, an igniter 9, and a diode 10.

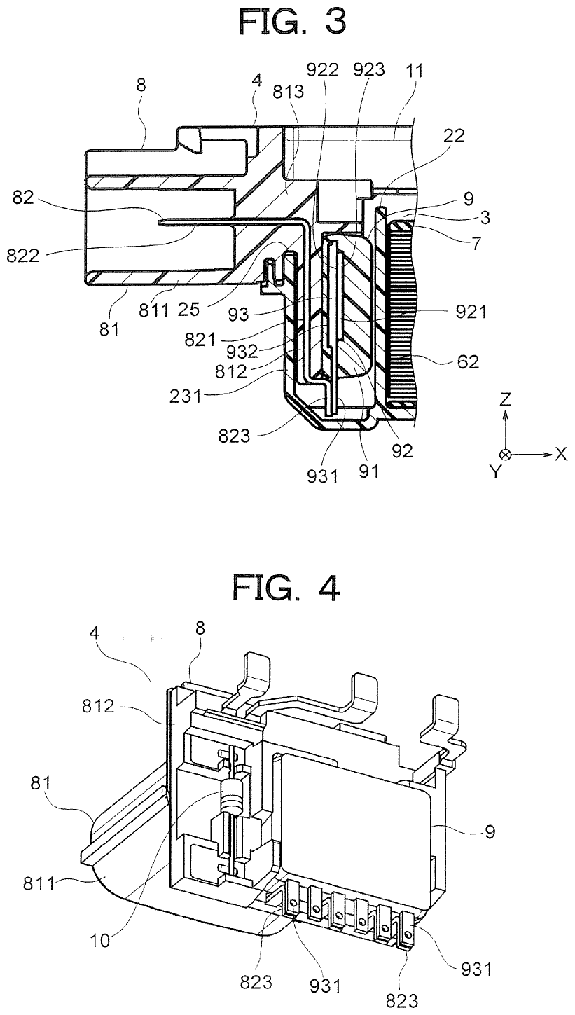

Now, FIG. 3 is an enlarged view for illustrating the connector module 4 of FIG. 2. Further, FIG. 4 is a perspective view for illustrating the connector module 4 of FIG. 3. The connector 8 is provided to the case main body 21. Further, the connector 8 includes a connector support portion 81 and a plurality of connector conductors 82.

The connector support portion 81 is made of an insulating material. As the material forming the connector support portion 81, a resin is used. The connector support portion 81 is mounted on the first opposed wall 231 in which the cutout portion 25 is formed. The connector support portion 81 includes a connector protruding portion 811 and a connector mounting portion 812.

The connector mounting portion 812 is housed in the second space of the case main body 21. Further, the connector mounting portion 812 is arranged along the first opposed wall 231 in which the cutout portion 25 is formed. A portion of the connector mounting portion 812 serves as a closing portion 813 configured to close the cutout portion 25. Therefore, the closing portion 813 of the connector mounting portion 812 serves as a part of walls forming the second space of the case main body 21. The closing portion 813 of the connector mounting portion 812 is fitted into an inner peripheral portion of the cutout portion 25.

The connector protruding portion 811 protrudes from the closing portion 813 of the connector mounting portion 812 to the outside of the case main body 21. The connector protruding portion 811 protrudes from the connector mounting portion 812 along the depth direction X of the ignition coil device 1. The connector protruding portion 811 has a tubular shape.

When the connector support portion 81 is mounted on the case main body 21, the closing portion 813 of the connector mounting portion 812 is pressed into the cutout portion 25 while the connector mounting portion 812 is inserted into the second space of the case main body 21 along the first opposed walls 231. As a result, the connector support portion 81 is mounted on the case main body 21.

The plurality of connector conductors 82 are arranged at intervals in the width direction Y of the ignition coil device 1. Each of the connector conductors 82 is a strip conductor. Each of the connector conductors 82 is arranged with a width direction of the connector conductor 82, which is the same with the width direction Y of the ignition coil device 1.

Each of the connector conductors 82 includes a conductor opposing portion 821, a connector first terminal 822, and a connector second terminal 823. The conductor opposing portion 821 is buried in the connector mounting portion 812. The connector first terminal 822 protrudes from one end of the conductor opposing portion 821 to space inside the connector protruding portion 811. The connector second terminal 823 protrudes from the other end of the conductor opposing portion 821 to the second space of the case main body 21.

In each of the connector conductors 82, the conductor opposing portion 821 is arranged along the thickness direction Z of the ignition coil device 1. Further, in each of the connector conductors 82, the connector first terminal 822 is arranged along the depth direction X of the ignition coil device 1.

To the connector protruding portion 811, a vehicle harness including a plurality of wires is connected. When the connector protruding portion 811 is connected to the vehicle harness, the plurality of wires in the vehicle harness are electrically connected to corresponding connector first terminals 822, respectively. As a result, power supply from a power source to the connector conductors 82 is enabled through the vehicle harness.

The igniter 9 and the diode 10 are mounted on the connector mounting portion 812. Further, the igniter 9 and the diode 10 are housed in the second space of the case main body 21. The igniter 9 and the diode 10 are arranged at positions closer to the ignition coil device main body 3 than the connector mounting portion 812 is. In other words, the igniter 9 and the diode 10 are arranged between the connector 8 and the ignition coil device main body 3. The rib 22 is arranged between the igniter 9 and the ignition coil device main body 3. A distance between the igniter 9 and the ignition coil device main body 3 is about 1.5 mm.

In the internal space of the case main body 21, a filler 11 covering the ignition coil device main body 3, the igniter 9, and the diode 10 is filled. Therefore, the ignition coil device main body 3, the igniter 9, and the diode 10 are buried in the filler 11. The rib 22 is also buried in the filler 11. The filler 11 is interposed in a gap between the connector mounting portion 812 and the first opposed wall 231, a gap between the igniter 9 and the connector mounting portion 812, a gap between the rib 22 and the igniter 9, and a gap between the ignition coil device main body 3 and the rib 22.

As a material forming the filler 11, a thermosetting insulating resin is used. In the first embodiment, an epoxy resin or a polybutylene terephthalate (PBT) resin is used as the material of the filler 11. As the material of the filler 11, an elastomer or a silicone may be used. Each of the connector support portion 81, the insulating case 2, and the filler 11 has a thermal conductivity of 0.5 W/m·K or less.

The igniter 9 is a switching module configured to control power supply to the ignition coil device main body 3. The igniter 9 is configured to control the power supply to the ignition coil device main body 3 by switching between execution of the power supply to the ignition coil device main body 3 and a stop of the power supply to the ignition coil device main body 3. The igniter 9 includes a molded member 91, a circuit board 92, and a plurality of lead frames 93.

The molded member 91 is made of an insulating material. As the material of the molded member 91, a resin is used. The molded member 91 covers the circuit board 92 and the plurality of lead frames 93. The molded member 91 is formed integrally with the circuit board 92 and the plurality of lead frames 93 by molding with the resin. The molded member 91 has a thermal conductivity of 0.5 W/m·K or less.

The circuit board 92 is buried in the molded member 91. The circuit board 92 includes a substrate 921 and a switching control circuit (not shown).

The substrate 921 has a first surface 922 and a second surface 923 formed thereon. The first surface 922 and the second surface 923 are opposed to each other in a thickness direction of the substrate 921. The thickness direction of the substrate 921 is the same with the depth direction X of the ignition coil device 1. As a result, the substrate 921 is arranged in a state in which the first surface 922 faces the connector 8 and the second surface 923 faces the ignition coil device main body 3. The substrate 921 is made of an insulating material. As the material forming the substrate 921, a resin is used. The substrate 921 has a thermal conductivity of 0.5 W/m·K or less.

The plurality of lead frames 93 are provided on the first surface 922 of the substrate 921. Further, the plurality of lead frames 93 are arranged at intervals in the width direction Y of the ignition coil device 1. Each of the lead frames 93 is arranged along the thickness direction Z of the ignition coil device 1.

Each of the lead frames 93 is a conductor electrically connected to the switching control circuit. As a material forming the lead frames 93, a metal, for example, copper is used.

A portion of each of the lead frames 93 protrudes as an igniter terminal 931 from the inside of the molded member 91 to the outside of the molded member 91. To at least one of a plurality of the igniter terminals 931, the connector second terminal 823 of the connector conductors 82 is electrically connected. In the first embodiment, the connector second terminals 823 of the connector conductors 82 are electrically connected to two or more igniter terminals 931 of the plurality of igniter terminals 931 on a one-to-one basis. As a result, at least one of the plurality of connector conductors 82 is electrically connected to the circuit board 92 via the lead frame 93.

Each of the lead frames 93 has a thermal conductivity that is higher than the thermal conductivity of each of the molded member 91, the substrate 921, the connector support portion 81, the insulating case 2, the core cover 7, and the filler 11. As a result, each of the lead frames 93 serves as a heat radiating member configured to radiate heat transmitted from the circuit board 92.

The switching control circuit is provided on the second surface 923 of the substrate 921. The switching control circuit is a circuit including a plurality of electronic components. Further, the switching control circuit is electrically connected to the primary coil 512 of the ignition coil device main body 3. The switching control circuit is configured to supply power to the ignition coil device main body 3 by supplying, to the primary coil 512, power supplied to the circuit board 92 of the igniter 9. The control on the power supply to the ignition coil device main body 3 is performed by switching between the execution of the power supply to the primary coil 512 and the stop of the power supply to the primary coil 512 by the switching control circuit.

Each of the lead frames 93 has formed thereon a heat radiating surface 932 parallel to the first surface 922 of the substrate 921. Each of the lead frames 93 is arranged with the heat radiating surface 932 facing the connector 8.

At least one of the plurality of lead frames 93 is provided on the first surface 922 of the substrate 921 in a state of being opposed to the connector conductors 82. The lead frame opposed to the connector conductor 82 is opposed to the conductor opposing portion 821 of the connector conductor 82 in the depth direction X of the ignition coil device 1. Further, the lead frame 93 opposed to the connector conductor 82 is opposed to the conductor opposing portion 821 via the molded member 91, the connector mounting portion 812, and the filler 11. The lead frame 93 opposed to the connector conductor 82 is arranged with the heat radiating surface 932 being opposed to the conductor opposing portion 821.

The diode 10 is electrically connected to the secondary coil 522 via the conductor opposing portion 821. The diode 10 is configured to suppress a secondary voltage generated in the secondary coil 522 when the power is supplied to the primary coil 512.

Next, operation is described. When the power is supplied to the primary coil 512 of the ignition coil device main body 3 under the control of the circuit board 92, the magnetic fluxes are generated in the closed magnetic circuit of the core structure 6. As a result, the secondary voltage, which is higher than a primary voltage applied to the primary coil 512, is induced in the secondary coil 522. The induction of the secondary voltage in the secondary coil 522 causes a spark at the ignition plug.

The circuit board 92 generates heat by controlling the power supply to the ignition coil device main body 3. The heat generated in the circuit board 92 is transmitted to each of the lead frames 93 serving as the heat radiating member. A part of the heat transmitted to each of the lead frames 93 is transmitted to the connector conductor 82 via the igniter terminal 931. Another part of the heat transmitted to the lead frame 93 is transmitted to the conductor opposing portion 821 via the molded member 91, the connector mounting portion 812, and the filler 11 without being transmitted via the igniter terminal 931. In other words, a part of the heat transmitted to the lead frame 93 is transmitted to the conductor opposing portion 821 via an insulating material. As a result, the heat generated in the circuit board 92 is radiated to the outside of the ignition coil device 1 via the connector conductors 82.

In the ignition coil device 1 described above, the plurality of lead frames 93 as the heat radiating members are provided on the first surface 922 of the substrate 921. Further, at least one of the plurality of lead frames 93 is opposed to the connector conductor 82. Therefore, it is possible to make the heat generated in the circuit board 92 to be easily transmitted from the lead frame 93 to the connector conductor 82 via the insulating material. As a result, it is possible to make the heat generated in the circuit board 92 to be easily radiated to the outside of the ignition coil device 1, and suppress an increase in temperature of the igniter 9. Therefore, a reduction in performance of the igniter 9 can be suppressed, and hence a reduction in performance of the ignition coil device 1 can be suppressed.

Further, at least one of the plurality of lead frames is electrically connected to the connector conductor 82. Therefore, the lead frame 93 can be used to perform both of the function of the heat radiating member configured to radiate the heat generated in the circuit board 92 and the function of the conductor configured to electrically connect the connector conductor 82 to the circuit board 92. This eliminates the need to newly provide a heat radiating member to the igniter 9, and an increase in number of components of the igniter 9 can be suppressed. Therefore, it is possible to suppress complication of the structure of the igniter 9.

Further, the rib 22 and the filler 11 are interposed between the ignition coil device main body 3 and the igniter 9. Still further, each of the rib 22 and the filler 11 has the thermal conductivity of 0.5 W/m·K or less. Therefore, it is possible to make the heat generated in the circuit board 92 difficult to be transmitted from the igniter 9 to the ignition coil device main body 3. As a result, it is possible to suppress an increase in temperature of the ignition coil device main body 3, and to suppress a reduction in performance of the ignition coil device main body 3. Therefore, it is possible to further reliably suppress the reduction in performance of the ignition coil device 1.

### Second Embodiment

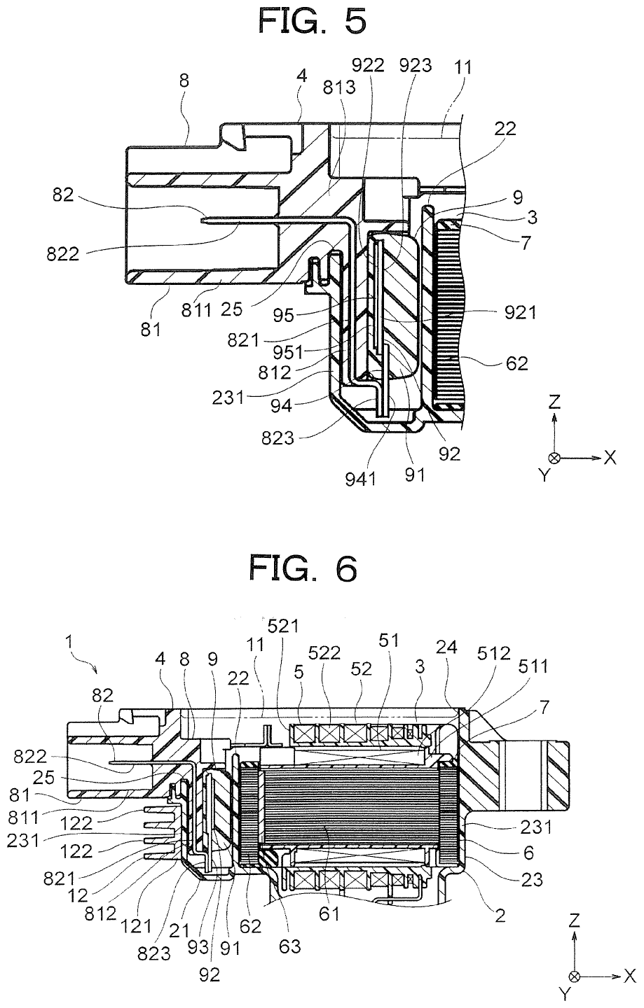

FIG. 5 is a sectional view for illustrating a main part of an ignition coil device according to a second embodiment of this disclosure. FIG. 5 is a view corresponding to FIG. 3 in the first embodiment. An igniter 9 includes a molded member 91, a circuit board 92, a plurality of lead frames 94, and a plurality of heat radiating members 95. The respective configurations of the molded member 91 and the circuit board 92 are the same as in the first embodiment. The plurality of heat radiating members 95 are members separate from the plurality of lead frames 94.

The plurality of lead frames 94 are electrically connected to the switching control circuit. In the second embodiment, the plurality of lead frames 94 are provided on the second surface 923 of the substrate 921. A portion of each of the lead frames 94 protrudes as an igniter terminal 941 from the inside of the molded member 91 to the outside of the molded member 91. To at least one of a plurality of the igniter terminals 941, the connector second terminal 823 of the connector conductor 82 is electrically connected. As a result, the connector conductor 82 is electrically connected to the circuit board 92. Power supplied from the power source to the connector conductor 82 is supplied to the circuit board 92 via the lead frame 94.

The plurality of heat radiating members 95 are provided on the first surface 922 of the substrate 921. Each of the heat radiating members 95 has formed thereon a heat radiating surface 951 parallel to the first surface 922 of the substrate 921. Each of the heat radiating members 95 is arranged with the heat radiating surface 951 facing the connector 8.

The plurality of heat radiating members 95 are provided on the first surface 922 of the substrate 921 in a state of being opposed to the plurality of connector conductors 82 on a one-to-one basis. The heat radiating members 95 opposed to the connector conductors 82 are opposed to the conductor opposing portions 821 of the connector conductors 82 in the depth direction X of the ignition coil device 1. Further, the heat radiating members 95 opposed to the connector conductors 82 are opposed to the conductor opposing portions 821 via the molded member 91, the connector mounting portion 812, and the filler 11. Each of the heat radiating members 95 opposed to the connector conductors 82 is arranged with the heat radiating surface 951 being opposed to the conductor opposing portion 821.

As a material forming the heat radiating members 95, a metal such as copper or aluminum is used. Each of the heat radiating members 95 has a thermal conductivity that is higher than the thermal conductivity of each of the molded member 91, the substrate 921, the connector support portion 81, the insulating case 2, the core cover 7, and the filler 11. Each of the heat radiating members 95 is configured to radiate the heat received from the circuit board 92 to each of the connector conductors 82.

The heat generated in the circuit board 92 is transmitted to each of the heat radiating members 95. A part of the heat transmitted to each of the heat radiating members 95 is transmitted to the conductor opposing portion 821 via the molded member 91, the connector mounting portion 812, and the filler 11. In other words, a part of the heat transmitted to each of the heat radiating members 95 is transmitted to the conductor opposing portion 821 via an insulating material. As a result, the heat generated in the circuit board 92 is radiated to the outside of the ignition coil device 1 via each of the connector conductors 82. The other components in the second embodiment are similar to those in the first embodiment.

In the ignition coil device 1 described above, the heat radiating members 95 opposed to the connector conductors 82 are members separate from the lead frames 94. Therefore, positions of the heat radiating members 95 can be determined independently of the positions of the lead frames 94. As a result, the heat radiating members 95 can be arranged more reliably at positions opposed to the connector conductors 82. Also with this configuration, it is possible to make the heat generated in the circuit board 92 to be easily transmitted from the heat radiating members 95 to the connector conductors 82. As a result, the increase in temperature of the igniter 9 can be suppressed, and the reduction in performance of the ignition coil device 1 can be suppressed.

In the second embodiment, the plurality of heat radiating members 95 are provided on the first surface 922 of the substrate 921. However, the number of heat radiating members 95 provided on the first surface 922 of the substrate 921 may be one. In this case, one heat radiating member 95 is arranged so as to be opposed to the respective conductor opposing portions 821 of the plurality of connector conductors 82.

### Third Embodiment

FIG. 6 is a sectional view for illustrating an ignition coil device according to a third embodiment of this disclosure. An ignition coil device 1 includes an insulating case 2, an ignition coil device main body 3, a connector module 4, and a heat sink 12. Respective configurations of the insulating case 2, the ignition coil device main body 3, and the connector module 4 are similar to those in the first embodiment.

The heat sink 12 is provided on an outer surface of the case main body 21. Therefore, the heat sink 12 is exposed to the outside of the case main body 21. Further, the heat sink 12 is provided on one first opposed wall 231 of the case main body 21.

The heat sink 12 is opposed to at least one of the plurality of lead frames 93 via the connector conductors 82. Specifically, in the depth direction X of the ignition coil device 1, the heat sink 12 is opposed to at least one of the plurality of lead frames 93 via the conductor opposing portion 821 of the connector conductors 82. Between the heat sink 12 and the connector conductors 82, the first opposed wall 231, the connector mounting portion 812, and the filler 11 are interposed. A part of heat transmitted to the connector conductors 82 is transmitted to the heat sink 12 via the first opposed wall 231, the connector mounting portion 812, and the filler 11. In other words, a part of the heat transmitted to the connector conductors 82 is transmitted to the heat sink 12 via an insulating material.

The heat sink 12 is made of a metal, such as copper or aluminum. The heat sink 12 has a thermal conductivity that is higher than the thermal conductivity of each of the molded member 91, the substrate 921, the connector support portion 81, the insulating case 2, the core cover 7, and the filler 11. The heat transmitted to the heat sink 12 is radiated from the heat sink 12 to the outside of the ignition coil device 1. The heat sink 12 includes a base portion 121 and a plurality of fins 122.

The base portion 121 is a plate-like portion mounted on the first opposed wall 231. The base portion 121 is opposed to at least one of the plurality of lead frames 93 via the connector conductors 82.

The plurality of fins 122 protrude from the base portion 121 to the outside of the case main body 21. In the third embodiment, the plurality of fins 122 protrude from the base portion 121 in a direction separating away from the case main body 21 in the depth direction X of the ignition coil device 1. Further, in the third embodiment, the plurality of fins 122 are arranged at intervals in the thickness direction Z of the ignition coil device 1. The other components in the third embodiment are similar to those in the first embodiment.

In the ignition coil device 1 described above, the heat sink 12 is opposed to at least one of the plurality of lead frames 93 serving as heat radiating members via the connector conductors 82. Therefore, it is possible to make the heat transmitted from the lead frames 93 to the connector conductors to be easily transmitted to the heat sink 12 via the insulating material. As a result, it is possible to more reliably make the heat generated in the circuit board 92 to be easily radiated to the outside of the ignition coil device 1, and the increase in temperature of the igniter 9 can be suppressed more reliably. Therefore, the reduction in performance of the ignition coil device 1 can be suppressed more reliably.

In the third embodiment, the heat sink 12 is provided to the case main body 21 in the first embodiment. However, the heat sink 12 may be provided to the case main body 21 in the second embodiment.

### Fourth Embodiment

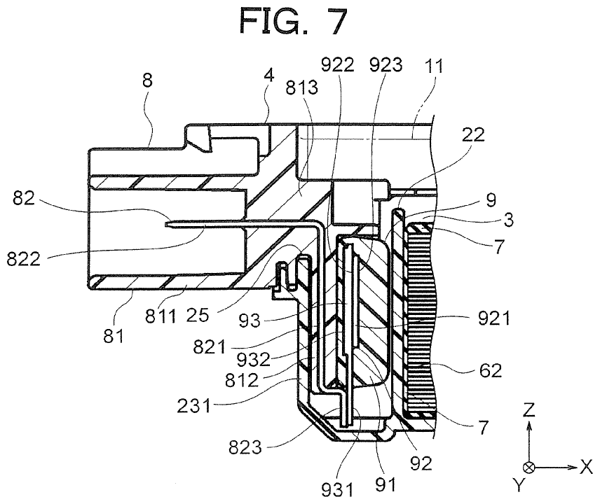

FIG. 7 is a sectional view for illustrating a main part of an ignition coil device according to a fourth embodiment of this disclosure. The core cover 7 covers a part of the side core 62. In the fourth embodiment, a portion of the inner peripheral surface of the side core 62 other than the portion to which the center core 61 is connected is covered by the core cover 7. Further, in the fourth embodiment, the both ends of the side core 62 in the thickness direction Z of the ignition coil device 1 are also covered by the core cover 7. Still further, in the fourth embodiment, the outer peripheral surface of the side core 62 is also covered by the core cover 7. As a result, the rib 22, the filler 11, and the core cover 7 are interposed between the igniter 9 and the side core 62. The core cover 7 has a thermal conductivity of 0.5 W/m·K or less. The other components are similar to those in the first embodiment.

In the ignition coil device 1 described above, the rib 22, the filler 11, and the core cover 7 are interposed between the igniter 9 and the side core 62. Therefore, it is possible to make the heat more difficult to be transmitted from the igniter 9 to the primary coil 512 and the secondary coil 522 of the ignition coil device main body 3. As a result, the increase in temperature of the ignition coil device main body 3 can be suppressed, and the reduction in performance of the ignition coil device 1 can be suppressed more reliably.

In the fourth embodiment, the configuration in which the outer peripheral surface of the side core 62 is covered by the core cover 7 is applied to the ignition coil device 1 according to the first embodiment. However, the configuration in which the outer peripheral surface of the side core 62 is covered by the core cover 7 may be applied to the ignition coil device 1 according to one of the second and third embodiments.

Further, in the first to fourth embodiments described above, each of the rib 22 and the filler 11 has the thermal conductivity of 0.5 W/m·K or less. However, as long as at least one of the rib 22 or the filler 11 has the thermal conductivity of 0.5 W/m·K or less, it is possible to make the heat difficult to be transmitted from the igniter 9 to the ignition coil device main body 3. As a result, the increase in temperature of the ignition coil device main body 3 can be suppressed, and the reduction in performance of the ignition coil device 1 can be suppressed.

What is claimed is:

1. An ignition coil device for an internal combustion engine, comprising:
an ignition coil device main body;
an igniter configured to control power supply to the ignition coil device main body;
an insulating case including a case main body housing the ignition coil device main body and the igniter; and
a connector provided to the case main body,
the case main body having internal space filled with a filler covering the ignition coil device main body and the igniter,
the igniter being arranged between the connector and the ignition coil device main body,
the igniter including a circuit board and a heat radiating member provided on the circuit board,
the connector including a connector conductor electrically connected to the circuit board,
the circuit board including a substrate having a first surface and a second surface formed thereon,
the substrate being arranged in a state in which the first surface faces the connector and the second surface faces the ignition coil device main body,
the heat radiating member having a thermal conductivity that is higher than a thermal conductivity of the substrate,
the heat radiating member being provided on the first surface in a state of being opposed to the connector conductor.

2. The ignition coil device for an internal combustion engine according to claim 1, wherein the heat radiating member is a lead frame electrically connected to the connector conductor.

3. The ignition coil device for an internal combustion engine according to claim 1,
wherein the insulating case includes the case main body and a rib provided inside the case main body,
wherein the rib and the filler are interposed between the ignition coil device main body and the igniter, and
wherein at least one of the rib or the filler has a thermal conductivity of 0.5 W/m·K or less.

4. The ignition coil device for an internal combustion engine according to claim 2,
wherein the insulating case includes the case main body and a rib provided inside the case main body,
wherein the rib and the filler are interposed between the ignition coil device main body and the igniter, and
wherein at least one of the rib or the filler has a thermal conductivity of 0.5 W/m·K or less.

5. The ignition coil device for an internal combustion engine according to claim 3,
wherein the ignition coil device main body includes a coil assembly, a center core to which the coil assembly is provided, a side core to which the center core is provided, and a core cover covering a part of the side core,
wherein the core cover is interposed between the igniter and one of the side core, and
wherein the core cover has a thermal conductivity of 0.5 W/m·K or less.

6. The ignition coil device for an internal combustion engine according to claim 4,
wherein the ignition coil device main body includes a coil assembly, a center core to which the coil assembly is provided, a side core to which the center core is provided, and a core cover covering a part of the side core,
wherein the core cover is interposed between the igniter and one of the side core, and
wherein the core cover has a thermal conductivity of 0.5 W/m·K or less.

7. The ignition coil device for an internal combustion engine according to claim 1, further comprising a heat sink which is provided to the case main body, and is exposed to the outside of the case main body,
wherein the heat sink is opposed to the heat radiating member via the connector conductor.

8. The ignition coil device for an internal combustion engine according to claim 2, further comprising a heat sink which is provided to the case main body, and is exposed to the outside of the case main body,
wherein the heat sink is opposed to the heat radiating member via the connector conductor.

9. The ignition coil device for an internal combustion engine according to claim 3, further comprising a heat sink which is provided to the case main body, and is exposed to the outside of the case main body,
wherein the heat sink is opposed to the heat radiating member via the connector conductor.

10. The ignition coil device for an internal combustion engine according to claim 4, further comprising a heat sink which is provided to the case main body, and is exposed to the outside of the case main body,
wherein the heat sink is opposed to the heat radiating member via the connector conductor.

11. The ignition coil device for an internal combustion engine according to claim 5, further comprising a heat sink which is provided to the case main body, and is exposed to the outside of the case main body,
wherein the heat sink is opposed to the heat radiating member via the connector conductor.

12. The ignition coil device for an internal combustion engine according to claim 6, further comprising a heat sink which is provided to the case main body, and is exposed to the outside of the case main body,
wherein the heat sink is opposed to the heat radiating member via the connector conductor.
